(19) United States
(12) Patent Application Publication
(10) Pub. No.: US 2026/0215212 A1
(43) Pub. Date: Jul. 23, 2026

(54) APPARATUS CONFIGURED TO BOND AN ELECTRONIC COMPONENT

(71) Applicant: Micraft System Plus Co., Ltd., Taoyuan City (TW)

(72) Inventors: Sheng Che Huang, Taichung City (TW); Chingju Lin, Taichung City (TW)

(73) Assignee: Micraft System Plus Co., Ltd., Taoyuan City (TW)

(21) Appl. No.: 19/373,731

(22) Filed: Oct. 30, 2025

(30) Foreign Application Priority Data
Jan. 21, 2025 (TW) 114102485

(51) Int. Cl. H10P 72/00; G06T 7/00; H10W 72/00

(52) U.S. Cl. CPC H10P 72/0606; G06T 7/0004; H10P 72/0436; G06T 2207/30148; H10W 72/011; H10W 72/07141; H10W 72/07178

(57) ABSTRACT

An apparatus configured to bond an electronic component includes a bonding mechanism, a carrying platform, a confirming-image capturing mechanism, a positioning-image capturing mechanism, an energy generating mechanism, and a control unit. The bonding mechanism includes a bonding head having a reference mark and a positioning mark and grabbing an electronic component to be bonded to be placed at a desired bonding position. The carrying platform is configured to carry a substrate to be bonded. The carrying platform and the bonding head are oppositely disposed. The confirming-image capturing mechanism captures an image between the reference mark and the electronic component. The positioning-image capturing mechanism captures an image of a part of the substrate through the positioning mark. The energy generating mechanism provides energy to the bonding head. The control unit instructs the bonding head and/or the carrying platform to actuate and complete bonding according to information from the confirming-image capturing mechanism.

### CROSS-REFERENCE TO RELATED APPLICATION

This application claims the priority benefit of Taiwan application serial no. 114102485, filed on January 21, 2025. The entirety of the above-mentioned patent application is hereby incorporated by reference herein and made a part of this specification.

### BACKGROUND

### Technical Field

The disclosure relates to an apparatus, and more particularly to an apparatus configured to bond an electronic component.

### Description of Related Art

During a manufacturing process of an electronic product, there is often a related electronic component transfer step. For example, during a manufacturing process of a light emitting diode (LED) display panel, a pick-and-place apparatus is often used to transfer a light emitting diode from one substrate to another substrate.

However, during the process of transferring an electronic component, a light emitting diode, or a micro light emitting diode from one substrate to another substrate, it is not always possible to place the electronic component, the light emitting diode, or the micro light emitting diode to be bonded at the correct bonding position.

### SUMMARY

The disclosure provides an apparatus configured to bond an electronic component, which can effectively improve the accuracy of bonding an electronic component to be bonded to a desired bonding position on a substrate to be bonded.

An apparatus configured to bond an electronic component of the disclosure includes a bonding mechanism, a carrying platform, a confirming-image capturing mechanism, a positioning-image capturing mechanism, an energy generating mechanism, and a control unit. The bonding mechanism has a bonding head. The bonding mechanism grabs an electronic component to be bonded by the bonding head, and places the electronic component to be bonded at a desired bonding position to perform bonding. A reference mark and a positioning mark are provided on the bonding head. The carrying platform is configured to carry a substrate to be bonded. The carrying platform and the bonding head of the bonding mechanism are disposed opposite to each other. The confirming-image capturing mechanism captures an image between the reference mark on the bonding head and the electronic component to be bonded grabbed by the bonding head. The positioning-image capturing mechanism captures an image of the substrate to be bonded carried by a part of the carrying platform through the positioning mark on the bonding head. The energy generating mechanism provides an energy to the bonding head of the bonding mechanism to perform bonding. The control unit instructs the bonding head and/or the carrying platform to actuate according to information from the confirming-image capturing mechanism, and enables the bonding head to complete actuation of bonding.

Based on the above, the displacement starting point and the relative displacement amount between the bonding head of the bonding mechanism and the carrying platform are determined through the positioning mark, and the image between the reference mark and the electronic component to be bonded is obtained by the confirming-image capturing mechanism. After computational processing through the control unit, by adjusting the relative position of the substrate to be bonded and the bonding head, the accuracy of bonding the electronic component to be bonded to the desired bonding position on the substrate to be bonded can be effectively improved.

### BRIEF DESCRIPTION OF THE DRAWINGS

FIG. 1 is a partial side schematic view of an apparatus configured to bond an electronic component according to an embodiment of the disclosure.

FIG. 2 is a partial side schematic view of an apparatus configured to bond an electronic component according to another embodiment of the disclosure.

FIG. 3A and FIG. 3B are partial bottom schematic views of an actuation manner of an apparatus configured to bond an electronic component according to an embodiment of the disclosure.

FIG. 4A and FIG. 4B are partial top schematic views of another actuation manner of an apparatus configured to bond an electronic component according to an embodiment of the disclosure.

FIG. 5A and FIG. 5B are partial top schematic views of yet another actuation manner of an apparatus configured to bond an electronic component according to an embodiment of the disclosure.

### DESCRIPTION OF THE EMBODIMENTS

The content of the following embodiments is provided for illustrative purposes only and are not intended to be limiting. Moreover, the description of well-known apparatuses, methods, and materials may be omitted so as not to obscure the description of various principles of the disclosure.

Directional terms used herein (for example, upper, lower) refer only to the illustrated usage or corresponding customary terms and are not intended to imply an absolute orientation. Therefore, unless otherwise specified, the directional terms used are intended to illustrate and not to limit the disclosure. Furthermore, in order to clearly indicate the directional relationship between different drawings, the Cartesian coordinate system (that is, the XYZ rectangular coordinate system) is used as an example in some drawings to represent the corresponding directions, but the disclosure is not limited thereto.

In some of the drawings, for clarity, some elements or film layers may be enlarged, reduced, or omitted at specific places or in specific directions. For example, in all the drawings, an electronic component (but not limited thereto) may be shown enlarged. Similar members are denoted by the same reference numerals and have similar functions, materials, or formation manners, and description thereof is omitted. It will be apparent to persons skilled in the art of the disclosure that the disclosure may be practiced in other embodiments that depart from the specific details disclosed herein by the content of the embodiments and the corresponding drawing illustrations.

In addition, unless the content clearly indicates otherwise, the singular form “a”, “an”, or “the” or forms without specifying a quantity may include one or multiple forms, that is, include “at least one”.

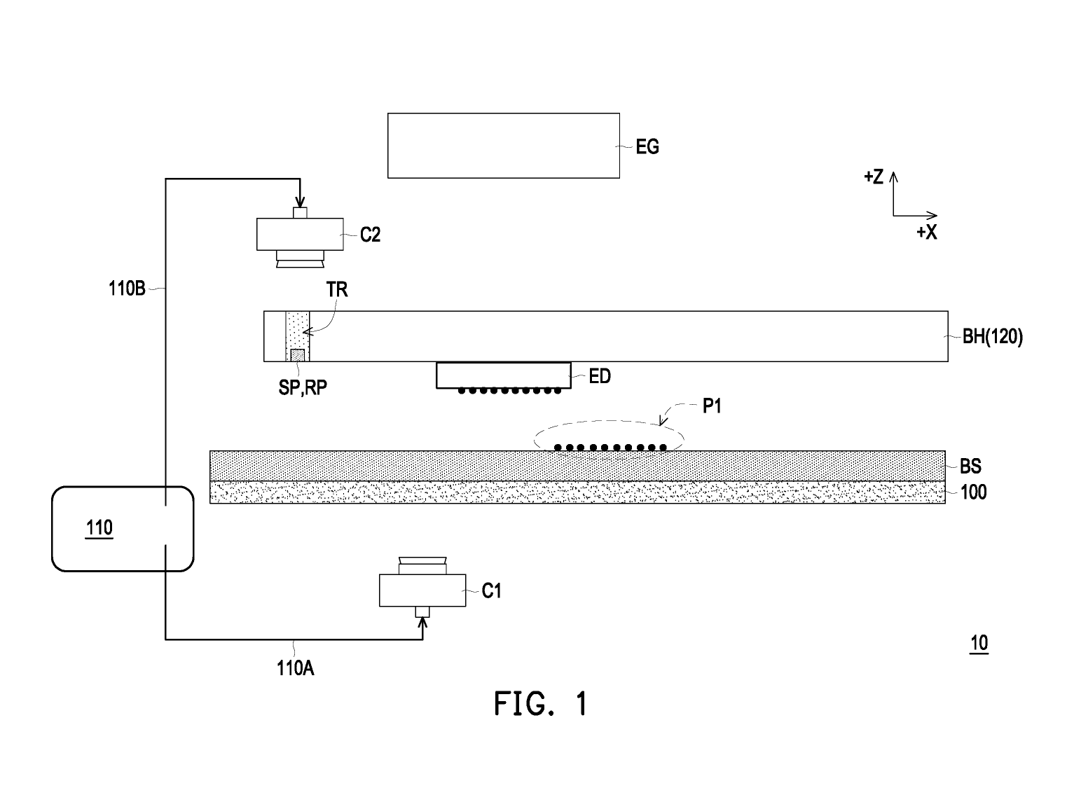

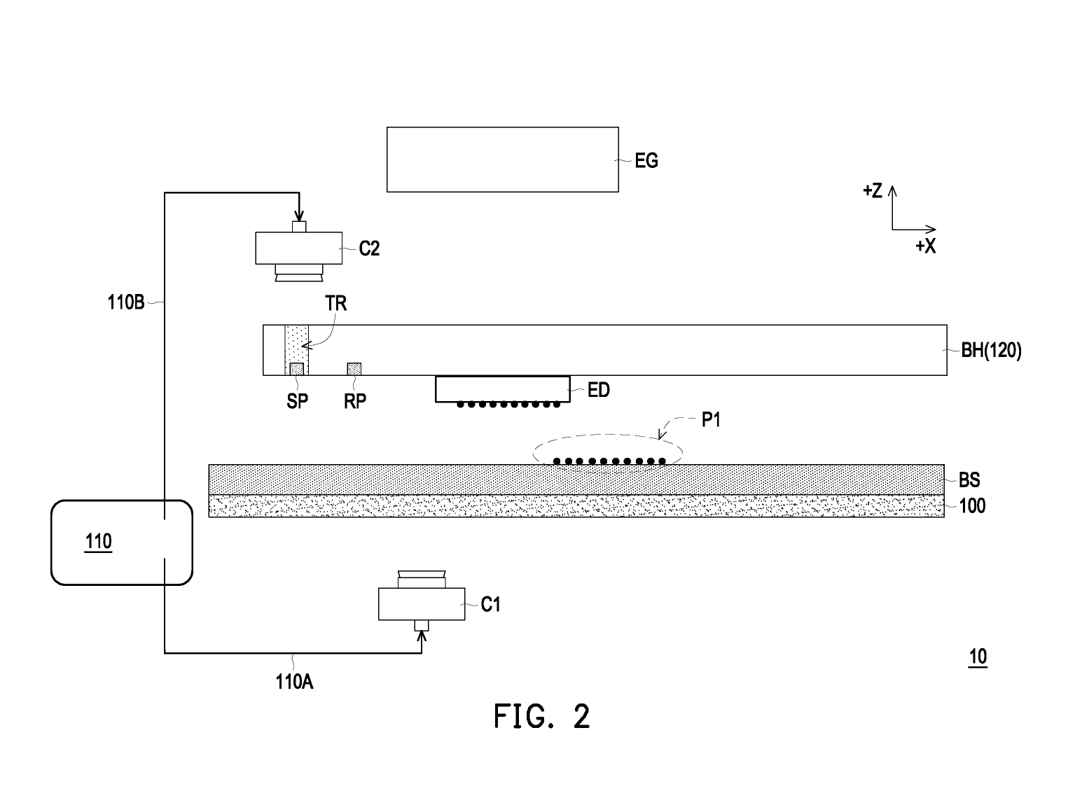

FIG. 1 or FIG. 2 is a side schematic view of an apparatus configured to bond an electronic component according to an embodiment of the disclosure.

Please refer to FIG. 1 or FIG. 2. An apparatus configured to bond an electronic component 10 may include a bonding mechanism 120, a carrying platform 100, a confirming-image capturing mechanism C1, a positioning-image capturing mechanism C2, an energy generating mechanism EG, and a control unit 110. It is worth noting that in FIG. 1 or other similar drawings, the apparatus configured to bond an electronic component 10 is only schematically illustrated. For clarity, some members may be omitted in FIG. 1 or other similar drawings. For example, the above mechanisms may be fixed by appropriate manners (for example, by corresponding screws, nuts, or screw holes; or by engaging, clamping, or coupling). For example, the above mechanisms may be suitable for changing positions or states (for example, move, rotate, or clamp) along corresponding directions by corresponding movable parts (for example, members such as motors, rollers, balls, gears, racks, toothed belts, and belts).

The bonding mechanism 120 includes a bonding head BH. A reference mark RP and a positioning mark SP are provided on the bonding head BH. The reference mark RP and/or the positioning mark SP are, for example, indentations, printings, or members with specific patterns, texts, or sizes suitable for being identified. The bonding head BH is suitable for grabbing an electronic component to be bonded ED, and placing the electronic component to be bonded ED at a desired bonding position P1 on a substrate to be bonded BS, so as to perform corresponding bonding. In an embodiment, the electronic component to be bonded ED is a chip, which may, for example, include a light emitting chip (for example, a light emitting diode chip, but not limited thereto) or an integrated circuit (IC) chip, but the disclosure is not limited thereto. In addition, for simplicity or clarity, only one electronic component to be bonded ED is shown in the drawings as an example.

In an embodiment, as shown in FIG. 1, the position of the reference mark RP and the position of the positioning mark SP may be close or even the same. For example, the reference mark RP may be located on the positioning mark SP. For another example, different places of the same pattern or text may be configured to respectively serve as the reference mark RP and the positioning mark SP.

In another embodiment, as shown in FIG. 2, the position of the reference mark RP and the position of the positioning mark SP may be different, and the difference in the positions may be identified by the naked eye or a suitable image capturing mechanism (for example, the confirming-image capturing mechanism C1 and the positioning-image capturing mechanism C2, but not limited thereto).

It should be noted that FIG. 1 or FIG. 2 is only schematically illustrated. For example, FIG. 1 and FIG. 2 may illustrate different apparatuses configured to bond an electronic component 10. For another example, FIG. 1 and FIG. 2 may illustrate the same apparatus configured to bond an electronic component 10, and FIG. 1 and FIG. 2 respectively illustrate the reference mark RP and the positioning mark SP in different side view directions or the reference mark RP and/or the positioning mark SP at different places. In other words, the number of the reference mark RP and/or the positioning mark SP of the apparatus configured to bond an electronic component 10 may be one or multiple, and the number, the position, the pattern, the text, or the size thereof may be adjusted according to application requirements.

The carrying platform 100 is configured to carry the substrate to be bonded BS. The substrate to be bonded BS may be an intermediate substrate in a mass transfer process, a circuit board with an appropriate circuit, or a circuit board further including an active component (for example, a thin film transistor array substrate, but not limited thereto), but the disclosure is not limited thereto. The carrying platform 100 and the bonding head BH of the bonding mechanism 120 are disposed opposite to each other.

The confirming-image capturing mechanism C1 may capture an image between the reference mark RP on the bonding head BH and the electronic component to be bonded ED grabbed by the bonding head BH. In an embodiment, the confirming-image capturing mechanism C1 may include a camera. In an embodiment, the confirming-image capturing mechanism C1 may project an appropriate light beam (for example, a photo flash or a continuous flash). Furthermore, a corresponding captured image may be obtained by reflection of light rays. In a possible embodiment, if an intensity of an ambient light is strong enough or there is another appropriate light source, the projection of the light beam may also be omitted (but not limited thereto, that is, the light beam may still be projected).

In an embodiment, the carrying platform 100 may be disposed between the bonding head BH and the confirming-image capturing mechanism C1. When the confirming-image capturing mechanism C1 intends to capture the reference mark RP on the bonding head BH, the electronic component to be bonded ED, or the image therebetween, the carrying platform 100 may move relative to the bonding head BH to provide sufficient space for the confirming-image capturing mechanism C1, so that the confirming-image capturing mechanism C1 is located at an appropriate position or has an appropriate depth of field (DOF), so as to be suitable for capturing an appropriate image.

The positioning-image capturing mechanism C2 may capture an image of the substrate to be bonded BS carried by a part of the carrying platform 100 through the positioning mark SP on the bonding head BH. In an embodiment, the positioning-image capturing mechanism C2 may include a camera. In the embodiment, the positioning-image capturing mechanism C2 may project an appropriate light beam (for example, a photo flash or a continuous flash). Furthermore, a corresponding captured image may be obtained by reflection of light rays. In a possible embodiment, if an intensity of an ambient light is strong enough or there is another appropriate light source, the projection of the light beam may be omitted (but not limited thereto, that is, the light beam may still be projected).

In an embodiment, the bonding head BH may be disposed between the positioning-image capturing mechanism C2 and the carrying platform 100. The bonding head BH may have a light transmitting region TR (the transmittance is, for example, greater than or equal to 50%, greater than or equal to 60%, greater than or equal to 70%, greater than or equal to 75%, greater than or equal to 80%, greater than or equal to 85%, greater than or equal to 90%, greater than or equal to 95%, or greater than or equal to 98%). In an embodiment, the positioning mark SP on the bonding head BH may be disposed within the light transmitting region TR.

In an embodiment, the entire bonding head BH is substantially light transmissive. In this way, the electronic component to be bonded ED may be bonded to the desired bonding position P1 on the substrate to be bonded BS by direct laser irradiation or other appropriate manners.

In another embodiment, only a part of the bonding head BH (for example, the light transmitting region TR) is light transmissive. In this way, energy may be provided to the desired bonding position P1 on the substrate BS by heat pressing or oblique laser irradiation, so as to bond the electronic component to be bonded ED to the desired bonding position P1.

The energy generating mechanism EG may provide energy to the bonding head BH of the bonding mechanism 120 to perform bonding. In an embodiment of the invention, the energy provided by the energy generating mechanism EG may include a light beam (for example, laser light) or thermal energy. For example, the energy generating mechanism EG may provide an infrared light beam (for example, a light beam with a wavelength of approximately 1064 nanometers (nm), but not limited thereto). For example, the light beam may be an infrared laser beam.

The control unit 100 may instruct the bonding head BH and/or the carrying platform 100 to actuate according to information from the confirming-image capturing mechanism C1, and enable the bonding head BH to complete the actuation of bonding.

In an embodiment, the control unit 110 may be signal-connected to a corresponding member (for example, the carrying platform 100, but not limited thereto), element, or mechanism (for example, the bonding mechanism 120, the carrying platform 100, the confirming-image capturing mechanism C1, the positioning-image capturing mechanism C2, and the energy generating mechanism EG, but not limited thereto) via wired signal transmission by a corresponding signal line (for example, a signal line 110A or a signal line 110B, but not limited thereto), but the disclosure is not limited thereto. In an embodiment, the control unit 110 may be signal-connected to a corresponding member, component, or unit via wireless signal transmission. In other words, the control unit 110 and the bonding mechanism 120, the carrying platform 100, the confirming-image capturing mechanism C1, the positioning-image capturing mechanism C2, and/or the energy generating mechanism EG signal-connected thereto may be considered as the same equipment or machine. In addition, the signal connection mentioned in the disclosure may generally refer to a connection manner of wired signal transmission or wireless signal transmission. In addition, the disclosure does not limit all signal connection manners to be the same or different.

In an embodiment, the control unit 110 may include corresponding hardware or software and may perform input, output, computation, storage, monitoring, data collection, statistics, and/or other appropriate operations. In an embodiment, the control unit 110 includes, for example, an input unit, an output unit, a computing unit, and/or a storage unit. The input unit includes, for example, a keyboard, a mouse, a touch screen, a signal receiving end (for example, a corresponding data port or antenna), and/or other similar units suitable for data input. The output unit includes, for example, a screen, a printer, a signal output end (for example, a corresponding data port or antenna), and/or other similar units suitable for data output. The computing unit includes, for example, a central processing unit (CPU), a graphics processing unit, a physics processing unit (PPU), or other similar units suitable for performing computation, logical judgment, and/or data processing. The storage unit includes, for example, a memory, a hard drive, a disk array, a database, and/or other similar units suitable for performing permanent or temporary data storage. In an embodiment, the control unit 110 includes, for example, software suitable for performing logical judgment or a platform and/or a programmable logic controller (PLC) suitable for performing advanced process control (APC), but the disclosure is not limited thereto.

In an embodiment, after receiving a corresponding image signal captured by the image capturing mechanism (for example, at least one of the confirming-image capturing mechanism C1 and the positioning-image capturing mechanism C2), the control unit 110 may perform calculation on the captured corresponding image. The calculation includes, but is not limited to, edge/boundary computing, alignment point computing, or displacement/shift computing for an object. Furthermore, the control unit 110 may determine, judge, or adjust the position (for example, the relative position between the bonding head BH and the carrying platform 100) or the state (for example, whether the bonding head BH is actuating) of the corresponding member, component, or mechanism according to a result of the calculation. For example, the position or displacement information (for example, displacement direction or displacement amount) of the bonding head BH of the bonding mechanism 120, the position or displacement information (for example, displacement direction or displacement amount) of the carrying platform 100, the relative position or relative displacement information (for example, relative displacement direction or relative displacement amount) between the bonding head BH and the carrying platform 100, or a part or all of the above information may be obtained by the corresponding image signal captured by the image capturing mechanism (for example, the confirming-image capturing mechanism C1). For another example, the position or the displacement information of the bonding head BH of the bonding mechanism 120 (for example, by the positioning mark SP on the bonding head BH) may be obtained by the corresponding image signal captured by the image capturing mechanism (for example, the positioning-image capturing mechanism C2). For another example, a displacement starting point may be determined by appropriate information (for example, position information of the bonding head BH, but not limited thereto), and the bonding head BH and the carrying platform 100 may be controlled or instructed to perform appropriate relative movements from the displacement starting point.

According to an exemplary embodiment of the disclosure, a mark (not shown in the drawings) is also provided at a place near the desired bonding position P1 on the substrate to be bonded BS at a spacing (reference value) from the desired bonding position P1. Next, an image is captured through the confirming-image capturing mechanism C1 to determine a spacing (target value) between the electronic component to be bonded ED on the bonding head BH and the reference mark RP and/or the positioning mark SP. The target value is compared with the reference value to determine the displacement amount (that is, the relative displacement amount). For example, if the target value is equal to the reference value, no displacement adjustment is required; and if the target value is different from the reference value, a displacement adjustment is performed according to a difference amount to align the electronic component to be bonded ED with the desired bonding position P1.

The manner of bonding the electronic component to be bonded ED to the substrate to be bonded BS by the apparatus configured to bond an electronic component 10 may be described as follows. However, it should be noted that the disclosure is not limited to the following manner. In other words, the apparatus configured to bond an electronic component 10 according to an embodiment may be used for any appropriate application.

Please refer to FIG. 1 or FIG. 2. The apparatus configured to bond an electronic component 10 is provided. Then, the following steps are performed in any order: the substrate to be bonded BS is disposed on the carrying platform 100, and the electronic component to be bonded ED is grabbed by the bonding head BH. At least one of the substrate to be bonded BS and the electronic component to be bonded ED may have corresponding solder to be suitable for subsequent bonding. Furthermore, the substrate to be bonded BS on the carrying platform 100 and the electronic component to be bonded ED are configured to face each other with a corresponding distance therebetween. Then, the following steps are performed in any order: the image is captured by the confirming-image capturing mechanism C1, and the image is captured by the positioning-image capturing mechanism C2. Then, the control unit 110 instructs the bonding head BH and/or the carrying platform 100 to actuate according to at least image information of the confirming-image capturing mechanism C1, and provides the energy to the bonding head BH by the energy generating mechanism EG to perform bonding, so as to complete the actuation of bonding. In the manner of bonding the electronic component to be bonded ED to the substrate to be bonded BS, one or more actuation manners that may be performed are described in detail below. However, it should be noted that the disclosure is not limited to the actuation manners described below.

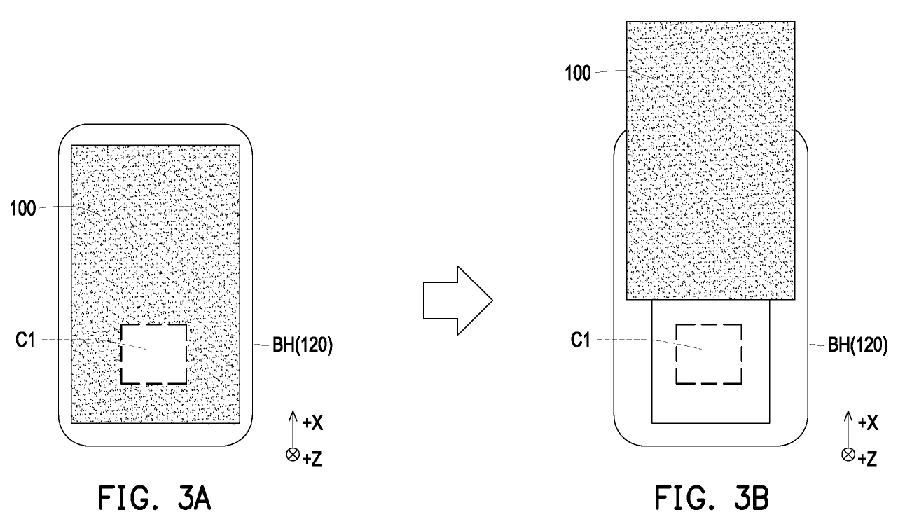

FIG. 3A and FIG. 3B are partial bottom schematic views of an actuation manner of an apparatus configured to bond an electronic component according to an embodiment of the disclosure. As shown in FIG. 3A and FIG. 3B, the carrying platform 100 is disposed between the bonding mechanism 120 and the confirming-image capturing mechanism C1.

Please refer to FIG. 3A and FIG. 3B. The carrying platform 100 and the substrate to be bonded BS thereon may be translated along an appropriate direction (for example, the +X direction, but not limited thereto) by being driven or controlled by the control unit 110, so that the confirming-image capturing mechanism C1 has an appropriate space or region to capture an appropriate image. Furthermore, after the confirming-image capturing mechanism C1 captures the image, the carrying platform 100 and the substrate to be bonded BS placed thereon may be restored to perform subsequent steps (such as bonding, but not limited thereto).

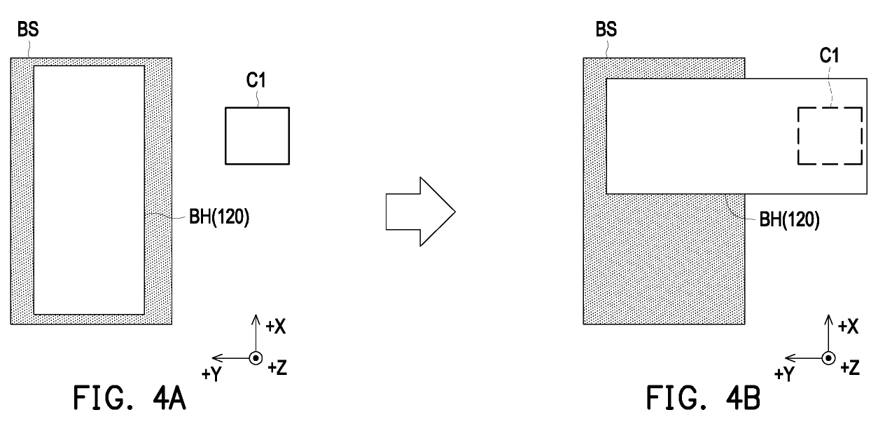

FIG. 4A and FIG. 4B are partial top schematic views of another actuation manner of an apparatus configured to bond an electronic component according to an embodiment of the disclosure. As shown in FIG. 4A and FIG. 4B, the confirming-image capturing mechanism C1 and the carrying platform 100 and the bonding mechanism 120 are disposed at different Y-axis positions.

Please refer to FIG. 4A and FIG. 4B. The control unit 110 drives or controls the bonding head BH to rotate in an appropriate direction (for example, counterclockwise, but not limited thereto), so that the confirming-image capturing mechanism C1 has an appropriate space or region to capture an appropriate image. Furthermore, after the confirming-image capturing mechanism C1 captures the image, the bonding head BH may be restored to perform subsequent steps (such as bonding but not limited thereto).

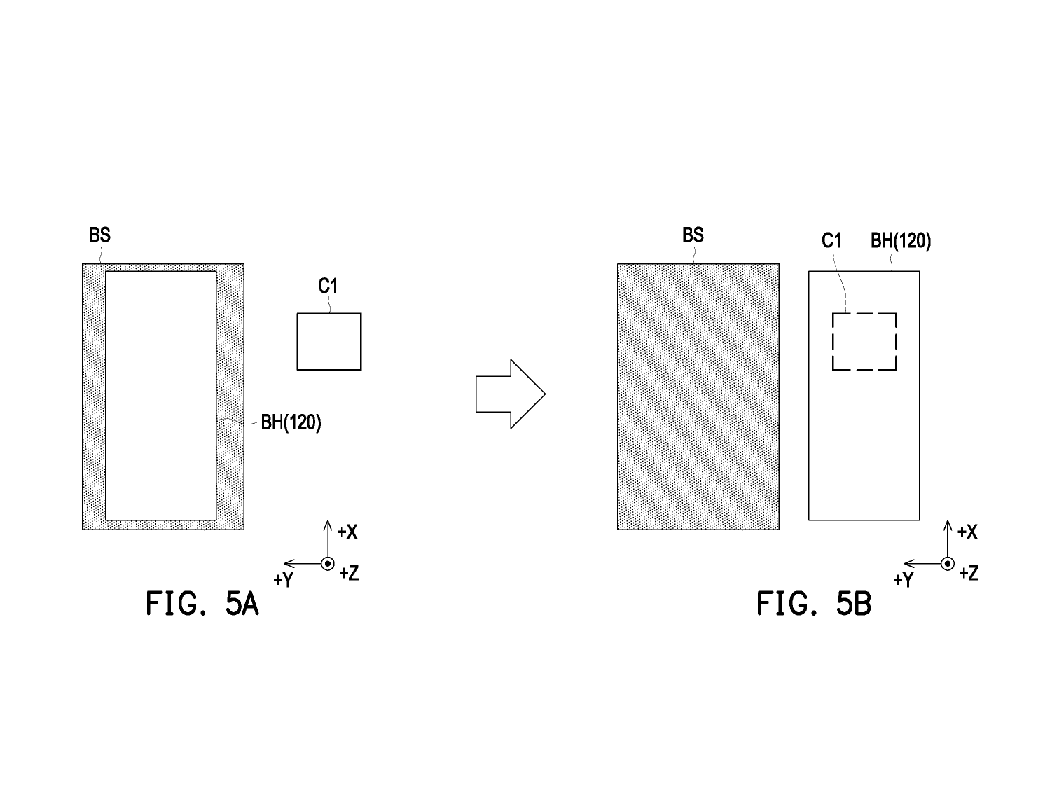

FIG. 5A and FIG. 5B are partial top schematic views of yet another actuation manner of an apparatus configured to bond an electronic component according to an embodiment of the disclosure. As shown in FIG. 5A and FIG. 5B, the confirming-image capturing mechanism C1 and the carrying platform 100 and the bonding mechanism 120 are disposed at different Y-axis positions.

Please refer to FIG. 5A and FIG. 5B. The control unit 110 drives or controls the bonding head BH to translate along an appropriate direction, so that the confirming-image capturing mechanism C1 has an appropriate space or region to capture an appropriate image. Furthermore, after the confirming-image capturing mechanism C1 captures the image, the bonding head BH may be restored to perform subsequent steps (such as bonding but not limited thereto).

It is worth noting that the actuation manners of FIG. 3A to FIG. 3B, FIG. 4A to FIG. 4B, and FIG. 5A to FIG. 5B are for illustration only, and the amplitude and the manner of movement and rotation are not limited thereto and may be arbitrarily integrated or adjusted.

In summary, the apparatus configured to bond an electronic component of the disclosure may accurately instruct to adjust the position of the carrying platform (together with the substrate to be bonded) or the bonding head through the setting of the positioning mark and the reference mark, the information provided by the confirming-image capturing mechanism and the positioning-image capturing mechanism, and the computation or the data processing of the control unit, so that the electronic component to be bonded may be more accurately bonded at the desired bonding position, that is, by adjusting the relative position of the substrate to be bonded and the bonding head, the accuracy of bonding the electronic component to be bonded to the desired bonding position on the substrate to be bonded can be effectively improved.

What is claimed is:

1. An apparatus configured to bond an electronic component, comprising:
a bonding mechanism, having a bonding head, wherein the bonding mechanism grabs an electronic component to be bonded by the bonding head, and place the electronic component to be bonded at a desired bonding position to perform bonding, wherein a reference mark and a positioning mark are provided on the bonding head;
a carrying platform, configured to carry a substrate to be bonded, wherein the carrying platform and the bonding head of the bonding mechanism are disposed opposite to each other;
a confirming-image capturing mechanism, capturing an image between the reference mark on the bonding head and the electronic component to be bonded grabbed by the bonding head;
a positioning-image capturing mechanism, capturing an image of the substrate to be bonded carried by a part of the carrying platform through the positioning mark on the bonding head;
an energy generating mechanism, providing an energy to the bonding head of the bonding mechanism to perform bonding; and
a control unit, instructing the bonding head and/or the carrying platform to actuate according to information from the confirming-image capturing mechanism, and enabling the bonding head to complete actuation of bonding.

2. The apparatus configured to bond an electronic component according to claim 1, wherein the reference mark is located on the positioning mark.

3. The apparatus configured to bond an electronic component according to claim 1, wherein the carrying platform is disposed between the bonding head and the confirming-image capturing mechanism, and when the confirming-image capturing mechanism intends to capture an image between the reference mark on the bonding head and the electronic component to be bonded, the carrying platform moves relative to the bonding head to provide the confirming-image capturing mechanism with a space sufficient to capture the image.

4. The apparatus configured to bond an electronic component according to claim 2, wherein the carrying platform is disposed between the bonding head and the confirming-image capturing mechanism, and when the confirming-image capturing mechanism intends to capture an image between the reference mark on the bonding head and the electronic component to be bonded, the carrying platform moves relative to the bonding head to provide the confirming-image capturing mechanism with a space sufficient to capture the image.

5. The apparatus configured to bond an electronic component according to claim 1, wherein the bonding head is disposed between the positioning-image capturing mechanism and the carrying platform, the bonding head has a light transmitting region, and the positioning mark is disposed within the light transmitting region.

6. The apparatus configured to bond an electronic component according to claim 2, wherein the bonding head is disposed between the positioning-image capturing mechanism and the carrying platform, the bonding head has a light transmitting region, and the positioning mark is disposed within the light transmitting region.

7. The apparatus configured to bond an electronic component according to claim 1, wherein the control unit obtains a relative displacement amount between the bonding head of the bonding mechanism and the carrying platform according to information from the confirming-image capturing mechanism, determines a displacement starting point through the positioning mark on the bonding head according to the positioning-image capturing mechanism, and instructs the bonding head and the carrying platform to relatively move by the relative displacement amount from the displacement starting point.

8. The apparatus configured to bond an electronic component according to claim 2, wherein the control unit obtains a relative displacement amount between the bonding head of the bonding mechanism and the carrying platform according to information from the confirming-image capturing mechanism, determines a displacement starting point through the positioning mark on the bonding head according to the positioning-image capturing mechanism, and instructs the bonding head and the carrying platform to relatively move by the relative displacement amount from the displacement starting point.

9. The apparatus configured to bond an electronic component according to claim 1, wherein the energy generating mechanism provides a thermal energy.

10. The apparatus configured to bond an electronic component according to claim 2, wherein the energy generating mechanism provides a thermal energy.

11. The apparatus configured to bond an electronic component according to claim 1, wherein the energy generating mechanism provides a laser beam.

12. The apparatus configured to bond an electronic component according to claim 2, wherein the energy generating mechanism provides a laser beam.

13. The apparatus configured to bond an electronic component according to claim 1, wherein the confirming-image capturing mechanism is a camera.

14. The apparatus configured to bond an electronic component according to claim 2, wherein the confirming-image capturing mechanism is a camera.

15. The apparatus configured to bond an electronic component according to claim 1, wherein the positioning-image capturing mechanism is a camera.

16. The apparatus configured to bond an electronic component according to claim 2, wherein the positioning-image capturing mechanism is a camera.

17. The apparatus configured to bond an electronic component according to claim 1, wherein the electronic component to be bonded is a chip.

18. The apparatus configured to bond an electronic component according to claim 2, wherein the electronic component to be bonded is a chip.
